(19) United States
(12) Patent Application Publication
(10) Pub. No.: US 2026/0309812 A1
(43) Pub. Date: Oct. 8, 2026

(54) SYSTEMS AND METHODS FOR FABRICATION OF A PART WITH AN EMBEDDED QUANTUM SENSOR

(71) Applicant: Toyota Motor Engineering & Manufacturing North America, Inc., Plano, TX (US)

(72) Inventors: Ercan M. Dede, Ann Arbor, MI (US); Paul Donald Schmalenberg, Ann Arbor, MI (US)

(73) Assignees: Toyota Motor Engineering & Manufacturing North America, Inc., Plano, TX (US); Toyota Jidosha Kabushiki Kaisha, Aichi-ken (JP)

(21) Appl. No.: 19/048,467

(22) Filed: Feb. 7, 2025

(51) Int. Cl. G01R 33/032; B82Y 15/00; B82Y 20/00; B82Y 40/00; G01R 33/26; H10D 62/00; H10D 62/60

(52) U.S. Cl. CPC G01R 33/032; B82Y 15/00; B82Y 20/00; B82Y 40/00; G01R 33/26; H10D 62/01; H10D 62/60

(57) ABSTRACT

A method and computer program product for fabricating a quantum sensor embedded within a part, and a part with a quantum sensor embedded within the part. The quantum sensor embedded within a part may be fabricated. The quantum sensor embedded within the part may include a quantum material hosting quantum vacancy defects. The quantum vacancy defects may have quantum color centers. The quantum vacancy defects, when exposed to a stimulus, may emit a measurable signal from the quantum color centers.

### BACKGROUND

Quantum Sensing stands at the forefront of sensor technology, revolutionizing the precision with which we measure, navigate, study, explore, perceive, and engage with our surroundings by detecting changes in motion, electric fields, and magnetic fields. The signal sensing generally occurs at the atomic level, leveraging quantum resources—subtle phenomena observable only on an atomic scale—to achieve unparalleled accuracy.

### Brief Summary of Disclosure

In one example implementation, a method may include but is not limited to fabricating a quantum sensor embedded within a part. The quantum sensor embedded within the part may include a quantum material hosting quantum vacancy defects. The quantum vacancy defects may have quantum color centers. The quantum vacancy defects, when exposed to a stimulus, may emit a measurable signal from the quantum color centers.

One or more of the following example features may be included. The quantum material may include functionalized nanodiamond particles, and the quantum vacancy defects may include one of nitrogen vacancy (NV) defects, SiC vacancy defects, and h-BN vacancy defects. The quantum material may include composite particles with a core-shell structure. Fabricating the quantum sensor embedded within the part may include creating the quantum vacancy defects. Fabricating the quantum sensor embedded within the part may include at least one of fabricating the quantum material hosting the quantum vacancy defects within a bulk substrate, and grinding the bulk substrate into another form. Fabricating the quantum sensor embedded within the part may include 3D printing the part using a plastic filament that is embedded with the quantum material hosting the quantum vacancy defects. 3D printing the part using the plastic filament that is embedded with the quantum material hosting the quantum vacancy defects may include at least one of: printing at least a first portion of the plastic filament that is embedded with the quantum material hosting the quantum vacancy defects using a first nozzle; and printing at least a second portion of the plastic filament without the quantum material hosting the quantum vacancy defects using a second nozzle. Fabricating the quantum sensor embedded within the part may include dip coating at least a portion of the part in a slurry of the quantum material hosting the quantum vacancy defects.

In another example implementation, a computer program product may reside on a computer readable storage medium having a plurality of instructions stored thereon which, when executed across one or more processors, may cause at least a portion of the one or more processors to perform operations that may include but are not limited to fabricating a quantum sensor embedded within a part. The quantum sensor embedded within the part may include a quantum material hosting quantum vacancy defects. The quantum vacancy defects may have quantum color centers. The quantum vacancy defects, when exposed to a stimulus, may emit a measurable signal from the quantum color centers.

One or more of the following example features may be included. The quantum material may include functionalized nanodiamond particles, and the quantum vacancy defects may include one of nitrogen vacancy (NV) defects, SiC vacancy defects, and h-BN vacancy defects. The quantum material may include composite particles with a core-shell structure. Fabricating the quantum sensor embedded within the part may include creating the quantum vacancy defects. Fabricating the quantum sensor embedded within the part may include at least one of fabricating the quantum material hosting the quantum vacancy defects within a bulk substrate, and grinding the bulk substrate into another form. Fabricating the quantum sensor embedded within the part may include 3D printing the part using a plastic filament that is embedded with the quantum material hosting the quantum vacancy defects. 3D printing the part using the plastic filament that is embedded with the quantum material hosting the quantum vacancy defects may include at least one of: printing at least a first portion of the plastic filament that is embedded with the quantum material hosting the quantum vacancy defects using a first nozzle; and printing at least a second portion of the plastic filament without the quantum material hosting the quantum vacancy defects using a second nozzle. Fabricating the quantum sensor embedded within the part may include dip coating at least a portion of the part in a slurry of the quantum material hosting the quantum vacancy defects.

In another example implementation, a part may include but is not limited to a quantum sensor embedded within the part. The quantum sensor embedded within the part may include a quantum material hosting quantum vacancy defects. The quantum vacancy defects may have quantum color centers. The quantum vacancy defects, when exposed to a stimulus, may emit a measurable signal from the quantum color centers.

One or more of the following example features may be included. The quantum material may include functionalized nanodiamond particles, and the quantum vacancy defects may include one of nitrogen vacancy (NV) defects, SiC vacancy defects, and h-BN vacancy defects. The quantum material may include composite particles with a core-shell structure. Fabricating the quantum sensor embedded within the part may include creating the quantum vacancy defects. Fabricating the quantum sensor embedded within the part may include at least one of fabricating the quantum material hosting the quantum vacancy defects within a bulk substrate, and grinding the bulk substrate into another form. Fabricating the quantum sensor embedded within the part may include 3D printing the part using a plastic filament that is embedded with the quantum material hosting the quantum vacancy defects. 3D printing the part using the plastic filament that is embedded with the quantum material hosting the quantum vacancy defects may include at least one of: printing at least a first portion of the plastic filament that is embedded with the quantum material hosting the quantum vacancy defects using a first nozzle; and printing at least a second portion of the plastic filament without the quantum material hosting the quantum vacancy defects using a second nozzle. Fabricating the quantum sensor embedded within the part may include dip coating at least a portion of the part in a slurry of the quantum material hosting the quantum vacancy defects.

The details of one or more example implementations are set forth in the accompanying drawings and the description below. Other possible example features and/or possible example advantages will become apparent from the description, the drawings, and the claims. Some implementations may not have those possible example features and/or possible example advantages, and such possible example features and/or possible example advantages may not necessarily be required of some implementations.

### BRIEF DESCRIPTION OF THE DRAWINGS

FIG. 1 is an example diagrammatic view of a quantum material according to one or more example implementations of the disclosure;

FIG. 2 is an example diagrammatic view of a quantum material optically detected magnetic resonance setup according to one or more example implementations of the disclosure;

FIG. 3 is an example flowchart of a fabrication process according to one or more example implementations of the disclosure;

FIG. 4 is an example diagrammatic view of a 3D printer according to one or more example implementations of the disclosure; and

FIG. 5 is an example flowchart of a fabrication process according to one or more example implementations of the disclosure.

Like reference symbols in the various drawings may indicate like elements.

### DETAILED DESCRIPTION

### System Overview:

Nanodiamonds are used to strengthen materials and parts due to their exceptional mechanical properties, including high hardness, excellent thermal conductivity, and chemical stability. These properties make nanodiamonds an ideal additive in various composites to enhance strength, wear resistance, and thermal stability. In polymer composites, nanodiamonds are added to materials like plastics and resins to create stronger, more durable composites with improved tensile strength, hardness, and impact resistance, making them suitable for applications in automotive, aerospace, and electronics industries where strength and lightweight characteristics are important. In metal matrix composites, nanodiamonds increase strength, hardness, and wear resistance by providing high hardness reinforcement within the metal matrix, which helps distribute stress and reduces deformation or wear over time, a valuable property for high-stress environments like tools and machining parts. Similarly, in ceramic composites, nanodiamonds improve toughness and thermal properties, allowing brittle ceramics to withstand greater mechanical stress. This results in enhanced fracture toughness, which is advantageous for cutting tools, coatings, and other applications requiring hard, wear-resistant materials. Additionally, nanodiamonds are used in lubricants and coatings to reduce friction and wear. By incorporating nanodiamonds into lubricants, manufacturers create low-friction surfaces that minimize part wear, prolonging machinery life and reducing maintenance needs. When added to coatings, nanodiamonds improve scratch resistance and durability, making surfaces more resilient to physical damage. Overall, nanodiamonds significantly enhance mechanical performance by making materials harder, more durable, and more wear-resistant. Their small size allows even distribution throughout composites, providing uniform reinforcement without adding significant weight, which is critical for industries that rely on high-strength, wear-resistant components. However, using nanodiamonds as quantum sensors in parts offers a unique and very different advantage unrelated to enhancing mechanical performance.

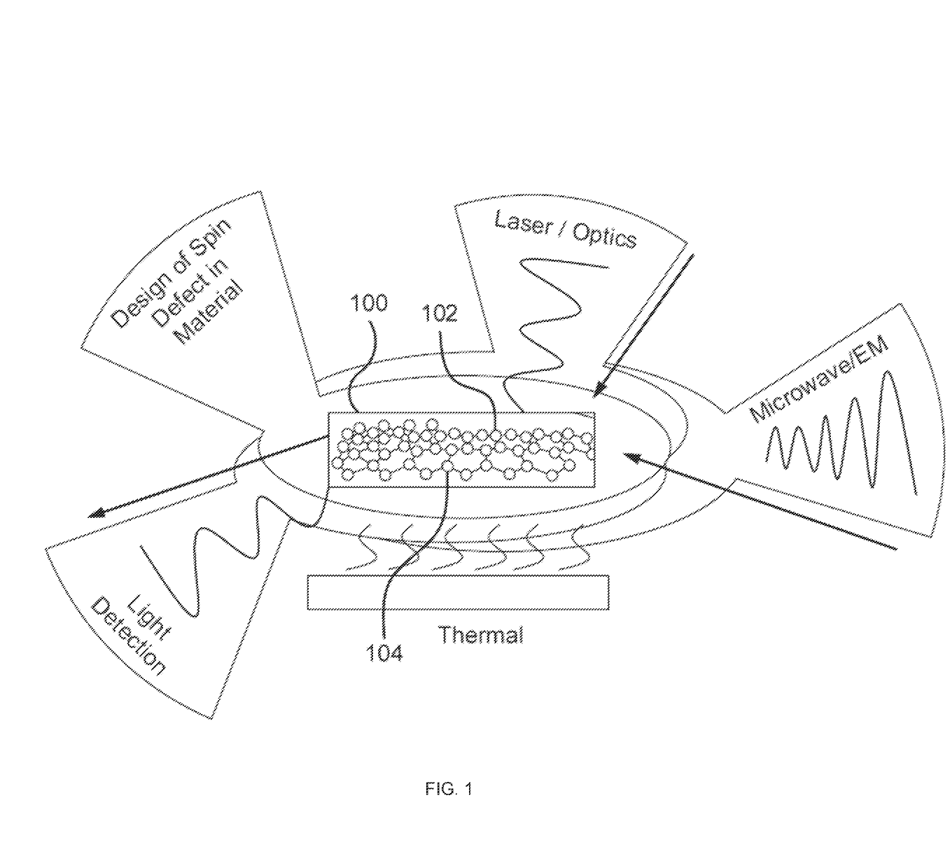

Quantum Sensing stands at the forefront of sensor technology, revolutionizing the precision with which we measure, navigate, study, explore, perceive, and engage with our surroundings by detecting changes in motion, electric fields, and magnetic fields. The signal sensing generally occurs at the atomic level, leveraging quantum resources—subtle phenomena observable only on an atomic scale—to achieve unparalleled accuracy. Quantum materials designed to have color centers are emerging as materials to provide quantum sensing. For instance, and referring at least to the example FIG. 1, a quantum material (e.g., quantum material 100) is shown. In the example, defects, such as Nitrogen Vacancy (NV) defects within the lattice structure of quantum material 100, such as diamonds, may be filled through various means with another element (e.g., element 102), such as nitrogen, which creates the color center (e.g., color center 104). The color centers may emit a light signal at a first wavelength in response to external stimuli, such as heat, strain, light at second wavelength, and magnetic fields, as shown in the example FIG. 1.

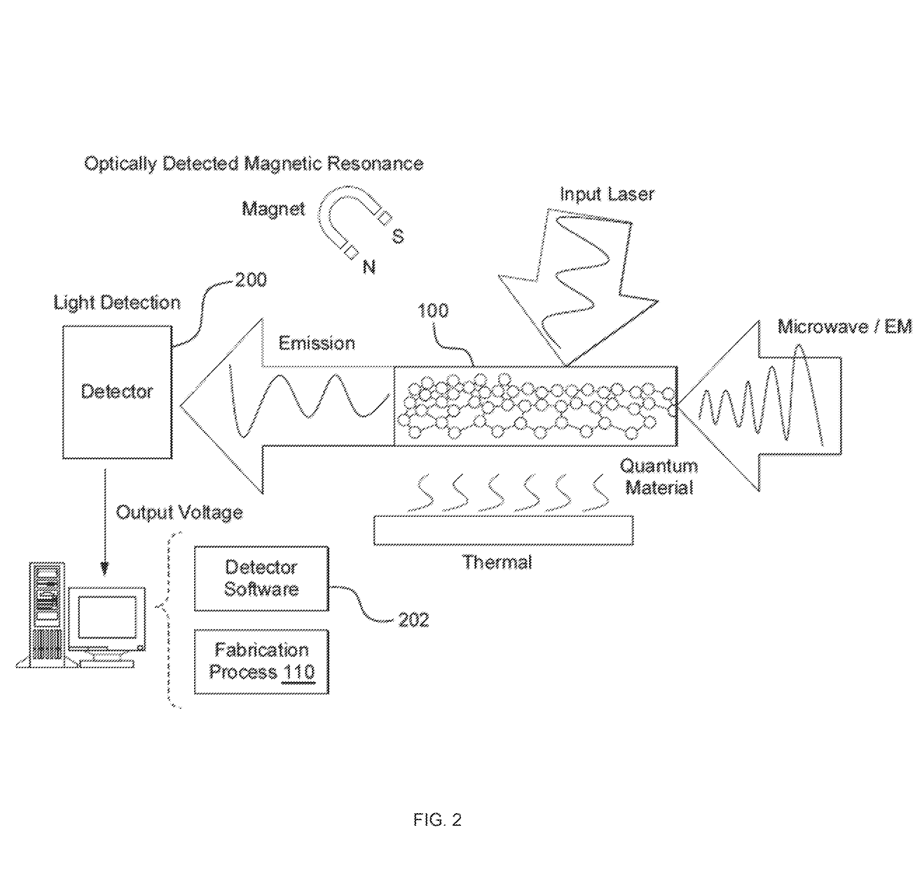

Referring now at least to the example FIG. 2, a detector (e.g., detector 200) is shown. The light signal emitted from the color centers in response to the external stimuli may be detected and measured using various techniques. For instance, quantum sensing using NV centers in diamonds may rely on both a sensing mechanism and a system for interpreting the sensor data. NV centers are quantum defects within the diamond lattice that act as sensitive “sensors” for detecting changes in magnetic, electric, and/or thermal fields in their environment. These NV centers are particularly useful because their quantum state—specifically their spin state—changes based on external environmental factors. Magnetic fields, for example, alter the spin properties of the NV center in a way that can be precisely detected and measured. To detect these changes, a laser or other light source (usually green) is used to excite the NV centers, causing them to emit red fluorescence. A microwave field can be generated by an appropriate microwave oscillator to modulate the NV center to extract hyper-fine lines, whose location hold information about and can shift in response to magnetic, electric, or thermal influences. By analyzing this emitted light, detailed information about the surrounding fields may be inferred.

For magnetic field detection, a technique called optically detected magnetic resonance (ODMR) may be used, where magnetic fields shift the NV center’s spin resonance frequencies due to the Zeeman effect. This shift can be detected by applying microwave pulses at specific frequencies and measuring the fluorescence output. Based on shifts in resonance, the magnetic field's strength and direction can be accurately determined. For electric and thermal field detection, the NV center’s energy levels respond subtly to electric fields, observable through slight changes in fluorescence patterns or spin state coherence. Temperature changes, meanwhile, affect the NV center through shifts in the diamond’s crystal lattice, altering the spin resonance frequency as a result of thermal expansion or phonon interactions (lattice vibrations).

The emitted fluorescence may be captured by detector 200, which may be a photodetector, such as photodiodes or highly sensitive cameras, which record variations in light intensity and spectrum. This photodetector data may then be processed by software 202 that interprets the fluorescence changes to calculate the values of magnetic, electric, or thermal fields. The software compares observed fluorescence with expected patterns for different field strengths, using the precise resonance frequency shifts to quantify the fields. Advanced algorithms, often incorporating machine learning, enhance accuracy by accounting for potential noise or interference. Interpreted data is often displayed in real-time, allowing researchers to observe field changes dynamically. This combination of NV center quantum defects, photodetection, and computational analysis makes NV-diamond sensors highly sensitive, providing detailed, real-time information about magnetic, electric, and thermal fields at the nanoscale.

While NV defects and diamonds are discussed, it will be appreciated after reading the present disclosure that other various quantum materials and defects may be used without departing from the present disclosure. For instance, quantum sensing does not strictly require nitrogen-vacancy (NV) centers or diamonds. Other types of quantum defects in different materials can also serve as effective quantum sensors, each with unique properties and potential advantages. Silicon carbide (SiC), for example, hosts quantum defects such as silicon vacancies, which share properties similar to NV centers. SiC is more economical to produce than diamond and compatible with standard semiconductor processing, making it ideal for integration into chip-based sensors. SiC functionalized for quantum sensing may also be formed in bulk and ground into a powder for embedding purposes similar to diamond. However, SiC is generally less stable and, in certain environments, less sensitive than diamond. Another material, hexagonal boron nitride (h-BN), contains boron vacancy defects that respond to magnetic fields and temperature shifts. h-BN is a two-dimensional material, well-suited for nanoscale sensing and integration into thin-film devices, though its sensors are still developing and often have shorter coherence times and lower sensitivity compared to NV centers in diamonds. Flakes of h-BN functionalized for quantum sensing may also be formed for embedding purposes. Rare-earth ions, like erbium or europium embedded in Yttrium orthosilicate (Y₂SiO₅), also exhibit long coherence times and can be tuned for magnetic and electric field sensing, though they require cryogenic cooling to function optimally, which limits their practicality for room-temperature applications.

Cold atom systems, where neutral atoms or ions are manipulated to respond to environmental fields, provide extremely high sensitivity for magnetic and electric field detection and flexibility in laboratory conditions. However, these systems typically require vacuum chambers and cooling lasers, making them bulky and challenging to miniaturize for practical, portable use.

Despite these alternatives, diamonds with NV centers provide a more ideal combination of stability, sensitivity, and room-temperature operation for quantum sensing applications. Diamonds are highly stable and biocompatible, able to operate under a wide range of environmental conditions, making them particularly suited to environmental sensing applications. NV centers also possess long coherence times at room temperature, high sensitivity to magnetic fields, and a fluorescence signature that can be easily read out optically, simplifying the detection process without requiring complex setups. Thus, as will be discussed in greater detail below, the present disclosure involves the fabrication of parts with embedded quantum materials with defects for the unique application determining the wear and tear of the parts, which may signal the need to replace the part before it is entirely necessary. By using functionalized nanodiamond particles with quantum color centers to form parts having quantum sensing capabilities, the parts themselves have an embedded inherent quantum sensor. Nonetheless, it will be appreciated after reading the present disclosure that the use of other functionalized powders or flakes for quantum sensing, such as SiC or h-BN, respectively, are conceivable in the current context for embedding into other materials/parts.

In some implementations, the present disclosure may be embodied as a method, system, or computer program product, e.g., via a fabrication process, such as fabrication process 110. Accordingly, in some implementations, the present disclosure (e.g., via fabrication process 110) may take the form of an entirely hardware implementation, an entirely software implementation (including firmware, resident software, micro-code, etc.) or an implementation combining software and hardware aspects that may all generally be referred to herein as a “circuit,” “module” or “system.” Furthermore, in some implementations, the present disclosure (e.g., via fabrication process 110) may take the form of a computer program product on a computer-usable storage medium having computer-usable program code embodied in the medium. Furthermore, in some implementations, the present disclosure (e.g., via fabrication process 110) may take the form of human actions, or a combination of human, hardware/software, computer program product actions. In some implementations, the hardware/software, computer program product actions may be executed on equipment commonly used in the semiconductor industry. For example, regarding simulation of the RF (radio frequency) characteristics, a variety of RF simulation software may be used, including but not limited to COMSOL, MATlab, Altium etc. Designing of the device may be done in a variety of computer aided design (CAD) software, such as AutoCAD, solidworks, etc. For fabrication, various equipment may be involved. Some of the more important ones being physical vapor deposition systems (e.g., magnetron sputtering, e-beam evaporation, etc. to deposit the metallic or insulating layers and for ion etching), spin coaters for coating of resist layers, laser writers and UV (ultraviolet) lithography machines for the lithography steps, scanning electron microscopes/optical microscopes for imaging and characterization, etc.

In some implementations, any suitable computer usable or computer readable medium (or media) may be utilized. The computer readable medium may be a computer readable signal medium or a computer readable storage medium. The computer-usable, or computer-readable, storage medium (including a storage device associated with a computing device or client electronic device) may be, for example, but is not limited to, an electronic, magnetic, optical, electromagnetic, infrared, or semiconductor system, apparatus, device, or any suitable combination of the foregoing. More specific examples (a non-exhaustive list) of the computer-readable medium may include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a digital versatile disk (DVD), a static random access memory (SRAM), a memory stick, a floppy disk, a mechanically encoded device such as punch-cards or raised structures in a groove having instructions recorded thereon, a media such as those supporting the internet or an intranet, or a magnetic storage device. Note that the computer-usable or computer-readable medium could even be a suitable medium upon which the program is stored, scanned, compiled, interpreted, or otherwise processed in a suitable manner, if necessary, and then stored in a computer memory. In the context of the present disclosure, a computer-usable or computer-readable, storage medium may be any tangible medium that can contain or store a program for use by or in connection with the instruction execution system, apparatus, or device.

In some implementations, a computer readable signal medium may include a propagated data signal with computer readable program code embodied therein, for example, in baseband or as part of a carrier wave. In some implementations, such a propagated signal may take any of a variety of forms, including, but not limited to, electro-magnetic, optical, or any suitable combination thereof. In some implementations, the computer readable program code may be transmitted using any appropriate medium, including but not limited to the internet, wireline, optical fiber cable, RF, etc. In some implementations, a computer readable signal medium may be any computer readable medium that is not a computer readable storage medium and that can communicate, propagate, or transport a program for use by or in connection with an instruction execution system, apparatus, or device.

In some implementations, computer program code for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java^{®}, Smalltalk, C++ or the like. Java^{®} and all Java-based trademarks and logos are trademarks or registered trademarks of Oracle and/or its affiliates. However, the computer program code for carrying out operations of the present disclosure may also be written in conventional procedural programming languages, such as the "C" programming language, PASCAL, or similar programming languages, as well as in scripting languages such as Javascript, PERL, or Python. The program code may execute entirely on the user's computer, partly on the user's computer, as a stand-alone software package, partly on the user’s computer and partly on a remote computer or entirely on the remote computer or server. In the latter scenario, the remote computer may be connected to the user’s computer through a local area network (LAN), a wide area network (WAN), a body area network BAN), a personal area network (PAN), a metropolitan area network (MAN), etc., or the connection may be made to an external computer (for example, through the internet using an Internet Service Provider). In some implementations, electronic circuitry including, for example, programmable logic circuitry, an application specific integrated circuit (ASIC), field-programmable gate arrays (FPGAs) or other hardware accelerators, micro-controller units (MCUs), or programmable logic arrays (PLAs) may execute the computer readable program instructions/code by utilizing state information of the computer readable program instructions to personalize the electronic circuitry, in order to perform aspects of the present disclosure.

In some implementations, the flowchart and block diagrams in the figures illustrate the architecture, functionality, and operation of possible implementations of apparatus (e.g., systems), methods and computer program products according to various implementations of the present disclosure. Each block in the flowchart and/or block diagrams, and combinations of blocks in the flowchart and/or block diagrams, may represent a human action, module, segment, or portion of code, which comprises one or more executable computer program instructions for implementing the specified logical function(s)/act(s). These computer program instructions may be provided to a processor of a general purpose computer, special purpose computer, or other programmable data processing apparatus to produce a machine, such that the computer program instructions, which may execute via the processor of the computer or other programmable data processing apparatus, create the ability to implement one or more of the functions/acts specified in the flowchart and/or block diagram block or blocks or combinations thereof. It should be noted that, in some implementations, the functions noted in the block(s) may occur out of the order noted in the figures (or combined or omitted). For example, two blocks shown in succession may, in fact, be executed substantially concurrently, or the blocks may sometimes be executed in the reverse order, depending upon the functionality involved.

In some implementations, these computer program instructions may also be stored in a computer-readable memory that can direct a computer or other programmable data processing apparatus to function in a particular manner, such that the instructions stored in the computer-readable memory produce an article of manufacture including instruction means which implement the function/act specified in the flowchart and/or block diagram block or blocks or combinations thereof.

In some implementations, the computer program instructions may also be loaded onto a computer or other programmable data processing apparatus to cause a series of operational steps to be performed (not necessarily in a particular order) on the computer or other programmable apparatus to produce a computer implemented process such that the instructions which execute on the computer or other programmable apparatus provide steps for implementing the functions/acts (not necessarily in a particular order) specified in the flowchart and/or block diagram block or blocks or combinations thereof.

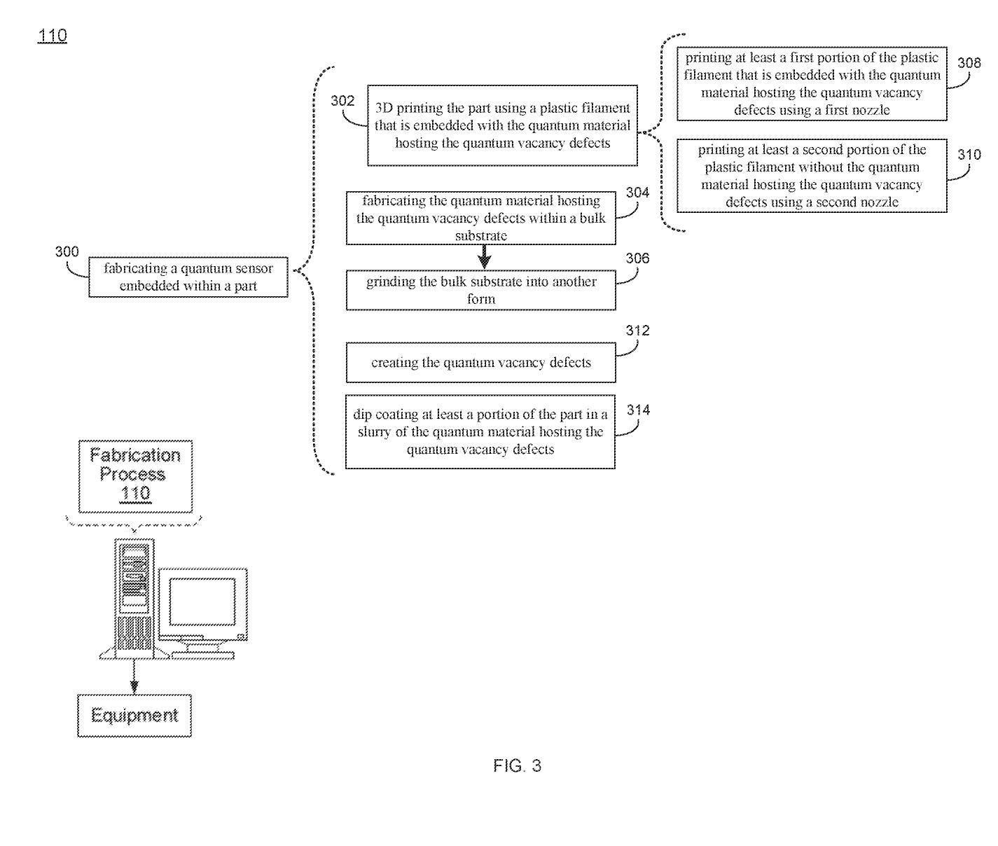

As discussed above and referring also at least to the example implementations of FIGS. 1-4, a fabrication process, such as fabrication process 110, may fabricate 300 a quantum sensor embedded within a part. The quantum sensor embedded within the part may include a quantum material hosting quantum vacancy defects. The quantum vacancy defects may have quantum color centers. The quantum vacancy defects, when exposed to a stimulus, may emit a measurable signal from the quantum color centers.

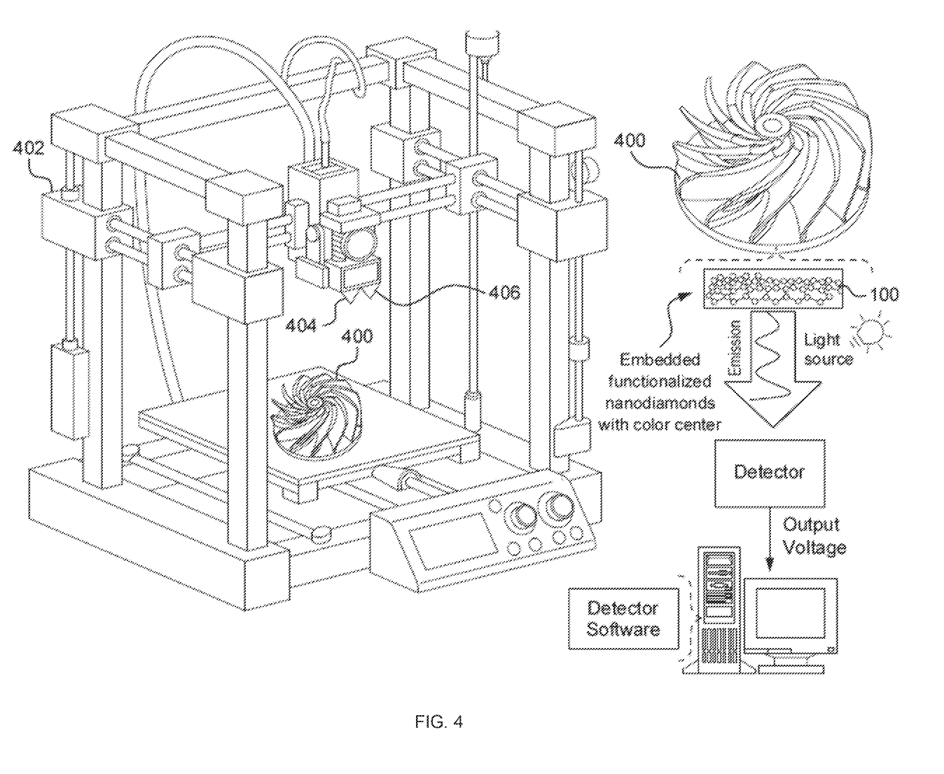

In some implementations, fabrication process 110 may fabricate 300 a quantum sensor embedded within a part. As discussed above, the quantum sensor embedded within the part may include a quantum material (e.g., fabricated nanodiamonds, or other feasible materials in particle, powder, or flake form) hosting quantum vacancy defects (e.g., NV defects, SiC vacancy defects, or h-BN vacancy defects). For instance, and referring at least to the example implementation of FIG. 4, an example part (e.g., part 400) is shown. In the example, part 400 is an impeller (or other spinning or rotating part), although it will be appreciated after reading the present disclosure that other parts of any form may be used without departing from the scope of the present disclosure. In the example, part 400 includes embedded functionalized nanodiamonds.

In some implementations, the quantum vacancy defects may have quantum color centers, such that the quantum vacancy defects, when exposed to a stimulus, may emit a measurable signal from the quantum color centers. For instance, quantum vacancy defects, such as nitrogen vacancy (NV) centers in diamonds, are created when atoms are missing or replaced within a crystal lattice, resulting in a “vacancy” next to an impurity atom, like nitrogen in diamonds. These defects form unique quantum systems that are highly sensitive to changes in their environment and can emit light in response to various stimuli, as discussed above. When such a defect forms, it creates a “quantum color center” within the crystal lattice, where the vacancy and impurity atom together establish a localized electronic structure. This structure allows the defect to absorb light at one wavelength and re-emit it at a different wavelength. For instance, in NV centers within diamonds, the nitrogen atom and adjacent vacancy form a stable color center that emits visible red fluorescence when excited by a green laser. The color and intensity of this emitted light are determined by the quantum state of the defect, which can be altered by magnetic, electric, or thermal fields.

The process of light emission from these quantum vacancy defects involves several example steps. First, the defect is exposed to a specific wavelength of light (often green for NV centers), which excites electrons within the defect’s structure to a higher energy level. These electrons then relax back to their ground state, releasing energy in the form of photons. The color of this emitted light depends on the structure of the color center, which in NV centers results in red fluorescence. The fluorescence emitted is affected by the quantum state of the defect, particularly the spin state in NV centers, which is influenced by external stimuli. For example, when a magnetic field is applied, it shifts the spin resonance of the NV center, leading to changes in the intensity or frequency of the emitted light. This change provides a measurable signal, which can indicate the presence, nature, and strength of the external stimulus.

When these quantum vacancy defects are exposed to environmental stimuli—such as magnetic, electric, or thermal fields—their electronic or spin state adjusts in response. In the case of NV color centers, the applied magnetic field modifies the spin resonance, directly affecting the emission pattern. By observing the emitted light with a detector, changes in light intensity or wavelength may be measured, allowing for precise and highly sensitive detection of environmental changes. This shift in emission characteristics essentially translates minute changes in the surrounding environment into detectable optical signals. Thus, quantum vacancy defects with color centers emit measurable signals in response to external stimuli by absorbing light, experiencing quantum state changes that reflect environmental influences, and emitting light with distinct color and intensity patterns based on that state, making them powerful tools for sensing applications, particularly when embedded into a part that is used a mechanical system, such as a vehicle.

In some implementations, fabricating the quantum sensor embedded within the part may include 3D printing 302 the part using a plastic filament that is embedded with the quantum material hosting the quantum vacancy defects. For instance, the fabrication may take place using 3D printing (e.g., fusion deposition modeling (FDM) 3D printing) parts using a plastic filament that is embedded with the functionalized nano-diamond particles having color centers. The nano-diamond particles, as noted above, have one or more defects that act as color centers. The functionalized nano-diamonds may be suspended in a plastic filament by embedding the material in the plastic filament prior to the printing process. A traditional FDM 3D printing process may then be used to fabricate the part. The result is a part having functionalized nano-diamonds with color centers embedded therein.

For instance, incorporating functionalized nanodiamonds with quantum color centers into part 400 created by FDM 3D printing may involve using a plastic filament, such as polylactic acid (PLA), that is embedded with nanodiamond particles. This approach begins with preparing a PLA filament in which functionalized nanodiamonds are suspended. During the filament manufacturing process, nanodiamond particles with color centers are mixed into the PLA resin before the filament is extruded. Ensuring that the nanodiamonds are well-dispersed in the PLA matrix is beneficial for achieving an even distribution of quantum material throughout the filament. After mixing, the PLA resin with embedded nanodiamonds is extruded into a continuous filament, resulting in a strand of PLA infused with nanodiamonds (and/or other functionalized quantum materials).

A consideration during this process is the preservation of the quantum properties of the nanodiamonds, specifically their color centers, which should remain intact through both filament manufacturing and 3D printing. To achieve this, the nanodiamonds may be functionalized before being mixed into the PLA. Functionalization typically involves surface treatments or coatings that protect the nanodiamonds from thermal or chemical degradation during filament extrusion and printing. These treatments ensure that the nanodiamonds (and/or other functionalized quantum materials) retain their quantum color centers and remain stable within the PLA matrix.

Once the PLA filament embedded with functionalized nanodiamonds is prepared, it can be used in an FDM 3D printer, such as 3D printer 402. The printer heats and extrudes the filament layer by layer to build the desired part, such as part 400. FDM printing typically heats the PLA to temperatures around 180–220° C, which is sufficient to melt and deposit the filament but low enough to avoid damaging the embedded nanodiamonds, especially if they are properly functionalized. During the printing process, the nanodiamonds remain suspended in the PLA matrix, ensuring that the quantum material is uniformly embedded within the printed structure.

After printing, the final part retains the nanodiamonds with intact quantum color centers embedded throughout the PLA structure. As a result, when the part is exposed to specific stimuli, such as light for excitation or magnetic fields, the nanodiamonds can still exhibit their characteristic fluorescence. By using a light source, one can excite the color centers in the embedded nanodiamonds, and a detector can capture the emitted signal. Since the nanodiamonds are uniformly distributed within the printed part, the entire part can function as a quantum sensor or serve as a component within a larger sensing system.

In some implementations, fabricating the quantum sensor embedded within the part may include fabricating 304 the quantum material hosting the quantum vacancy defects within a bulk substrate, grinding 306 the bulk substrate into another form (e.g., powder, particles, flakes, etc. of one or more types of materials. It will be appreciated after reading the present disclosure that the powder may have particles and/or flakes of one or more types of materials. For instance, to integrate quantum materials with vacancy defects into a 3D-printable filament, one example approach may be to first fabricate the quantum material within a bulk substrate, such as diamond or silicon carbide (SiC), and then grind this bulk material into a powder that can be embedded into a plastic filament. This process may begin with creating the quantum material with the desired vacancy defects, like NV centers in diamond or silicon/other complex vacancies in SiC, using techniques such as ion implantation, laser irradiation, or high-energy particle bombardment. These methods introduce defects within the substrate’s crystal lattice, which form the vacancy centers needed for quantum sensing. Additional treatments, such as annealing, may be applied to stabilize and optimize these defects, enhancing their quantum properties to ensure that they emit a reliable fluorescence or measurable signal in response to stimuli.

Once the quantum material with embedded vacancy defects is created in the bulk substrate, the next step is to grind the substrate into a fine powder. This grinding process may be carefully controlled, using specialized milling equipment like ball mills or planetary mills, to reduce the bulk material to nanoscale or microscale particles while preserving the quantum defects within each particle. The resulting powder consists of tiny particles that each host the vacancy defects and retain the ability to emit characteristic fluorescence or other measurable signals.

After grinding, this quantum material (particle or flaked-based) powder is mixed with a molten PLA (or similar) resin to create a composite filament. During this mixing process, the quantum powder particles are suspended within the PLA matrix, ensuring an even distribution throughout the filament. This step may need precise control to prevent clumping and achieve uniform dispersion of the quantum powder. The PLA resin with the embedded quantum powder is then extruded to form a filament, creating a 3D-printable material that contains the quantum defect particles throughout. With this PLA filament embedded with quantum material, standard FDM 3D printing can be used to fabricate the desired part as discussed above.

In some implementations, 3D printing the part using the plastic filament that is embedded with the quantum material hosting the quantum vacancy defects may include at least one of: printing 308 at least a first portion of the plastic filament that is embedded with the quantum material hosting the quantum vacancy defects using a first nozzle (e.g., nozzle 404); and printing 310 at least a second portion of the plastic filament without the quantum material hosting the quantum vacancy defects using a second nozzle (e.g., nozzle 406). For example, a dual-nozzle FDM 3D printer may be used to fabricate parts with precisely placed quantum sensing materials by allowing different materials or composites to be extruded from separate nozzles (e.g., nozzle 404 and nozzle 406). In this setup, nozzle 404 could be loaded with PLA filament embedded with NV nanodiamonds (as discussed above), granting it quantum sensing capabilities, while nozzle 406 holds standard PLA filament without nanodiamonds. It will be appreciated after reading the present disclosure that nozzle 406 is not limited to printing PLA and other multi-material printing scenarios are conceivable. It will also be appreciated after reading the present disclosure that more than two nozzles and materials may also be used. This arrangement allows for selective deposition of the NV-enhanced PLA only in specific areas of the part, enabling strategic placement of the quantum sensing material only where needed, thereby reducing material costs and optimizing functionality. To implement this approach, the part may be designed in CAD software, with designated regions marked for the NV-enhanced PLA in areas where quantum sensing will be beneficial, such as those exposed to magnetic or thermal fields. The CAD model specifies which sections require quantum sensing material and which do not, creating a multi-material print file that instructs the printer to switch between nozzles as needed. During printing, the printer switches between the nozzles based on the design, activating the first nozzle loaded with NV-enhanced PLA only for the specified regions, while the second nozzle with standard PLA (or other polymer material) is used for the remainder of the part. This selective deposition ensures that the NV nanodiamond material is used only in the desired areas, reducing the overall cost of the part.

Generally, dual-nozzle FDM printers are designed to achieve excellent bonding between layers printed with different materials, so the NV-enhanced PLA and standard PLA adhere well to each other, creating a unified structure with consistent mechanical integrity. This means the printed part functions cohesively, with designated sections containing quantum sensing capabilities. By using the NV-enhanced PLA only in targeted locations, this approach enables the cost-effective production of parts with embedded quantum sensing functions, rather than distributing the more expensive NV material throughout the entire part. This method is particularly advantageous for applications where sensing is needed in specific regions, such as the surfaces or edges of a component that will interact with magnetic or electric fields. For instance, in the automotive industry, this selective embedding could be applied to a vehicle part that requires localized magnetic or temperature sensing. In a car, certain areas, such as regions near high-temperature engine components or around electrical systems, could contain NV material for monitoring magnetic fields or temperature fluctuations, while the rest of the part is printed with standard PLA to minimize costs. The dual-nozzle setup not only allows for the part to be optimized for both functionality and cost but also provides advanced sensing capabilities precisely where they are needed within complex geometries. This approach of using a dual-nozzle FDM printer with NV-enhanced and standard PLA filament enables the creation of 3D-printed parts with embedded quantum sensing capabilities, tailored for applications like vehicle parts, where sensing is beneficial in specific, targeted regions.

In some implementations, the quantum material may include composite particles with a core-shell structure. For instance, quantum materials embedded in 3D-printable filaments can include composite particles with a core-shell structure to enhance stability, functionality, and compatibility with the host matrix. These core-shell particles consist of a central “core” that provides quantum sensing capabilities, surrounded by an outer “shell” layer that protects and stabilizes the core. The core material, which may be composed of nanodiamonds with NV centers, is engineered to have quantum vacancy defects that act as the color centers, as noted above. The shell surrounding this core serves multiple roles, including protecting the quantum material from environmental factors, such as moisture, temperature changes, or chemical interactions, which could degrade its properties. Materials like silica (SiO₂) or polymer coatings may be used for the shell, ensuring the core’s quantum characteristics remain intact during filament extrusion and the 3D printing process.

In addition to protecting the core, the shell layer also improves the compatibility between the core-shell particles and the PLA matrix, preventing clumping and ensuring uniform distribution (i.e., dispersion) within the filament. This compatibility enhancement is beneficial for producing a filament that can be extruded smoothly and provides consistent quantum sensing capabilities throughout the printed part or part region. By using a compatible shell, core-shell particles are better dispersed in the PLA, allowing the printed structure to retain evenly distributed sensing abilities. The core-shell structure also allows the quantum core to withstand the thermal and mechanical stresses of FDM printing, preserving the NV centers’ functionality. Once embedded within the printed part, these core-shell particles continue to respond to external stimuli (such as magnetic or electric fields), while the shell layer ensures the core material remains accessible for excitation and detection in sensing applications.

Core-shell composite particles offer further customization options based on specific application requirements. For instance, the shell layer can be functionalized with chemical groups to enhance adhesion to various polymer matrices beyond PLA or to enable the material to sense specific environmental conditions more effectively. This tailored core-shell approach enables the design of quantum materials optimized for diverse applications, including creating complex parts with embedded quantum sensing capabilities.

In some implementations, fabricating the quantum sensor embedded within the part may include creating 312 (e.g., separately growing or otherwise creating) the quantum vacancy defects. For example, growing quantum vacancy defects, such as NV centers in diamond, may involve the creation of atomic-scale vacancies and the introduction of impurity atoms to form stable quantum defects. The first step may be selecting an appropriate host material that can support quantum vacancies; for NV centers, high-purity single-crystal diamond may be chosen for its robust lattice structure, stability, and compatibility with quantum applications, while silicon carbide (SiC) may be used for other types of vacancies. To form the quantum defect, impurity atoms like nitrogen are introduced near these vacancies. This can be achieved during crystal growth, where nitrogen is embedded within the lattice, or post-growth, using ion implantation, which involves directing nitrogen ions at the diamond surface to embed them at specific lattice depths. It will be appreciated after reading the present disclosure that a variety of means may be used to create the quantum defects.

Creating the actual vacancies may involve removing carbon atoms from the lattice. High-energy processes, such as electron irradiation, laser irradiation, or ion bombardment, are used to displace carbon atoms from their positions, leaving empty lattice sites, or vacancies, near the nitrogen atoms. This step may help ensure the vacancies are created close to the nitrogen atoms for forming stable NV centers. Following vacancy creation, the material undergoes a heat treatment known as annealing, typically at temperatures between 800°C and 1000°C. Annealing enables the vacancies and nitrogen atoms to migrate and pair up, forming the NV centers. This step stabilizes the NV centers and improves their quantum coherence properties, making them more suitable for sensing applications.

The concentration and distribution of NV centers are optimized to ensure the desired quantum properties. While higher densities of NV centers can improve signal strength, excessive concentrations can decrease coherence times due to interactions between defects, so a balance is struck based on application needs. The finished material may be tested using spectroscopic techniques to verify the presence and quantum characteristics of the NV centers. Additionally, functionalization may be applied, such as surface treatments or coatings, to enhance stability or compatibility for specific uses. For instance, coatings may improve biocompatibility or enhance optical readability, making the NV centers more effective for imaging and sensing purposes.

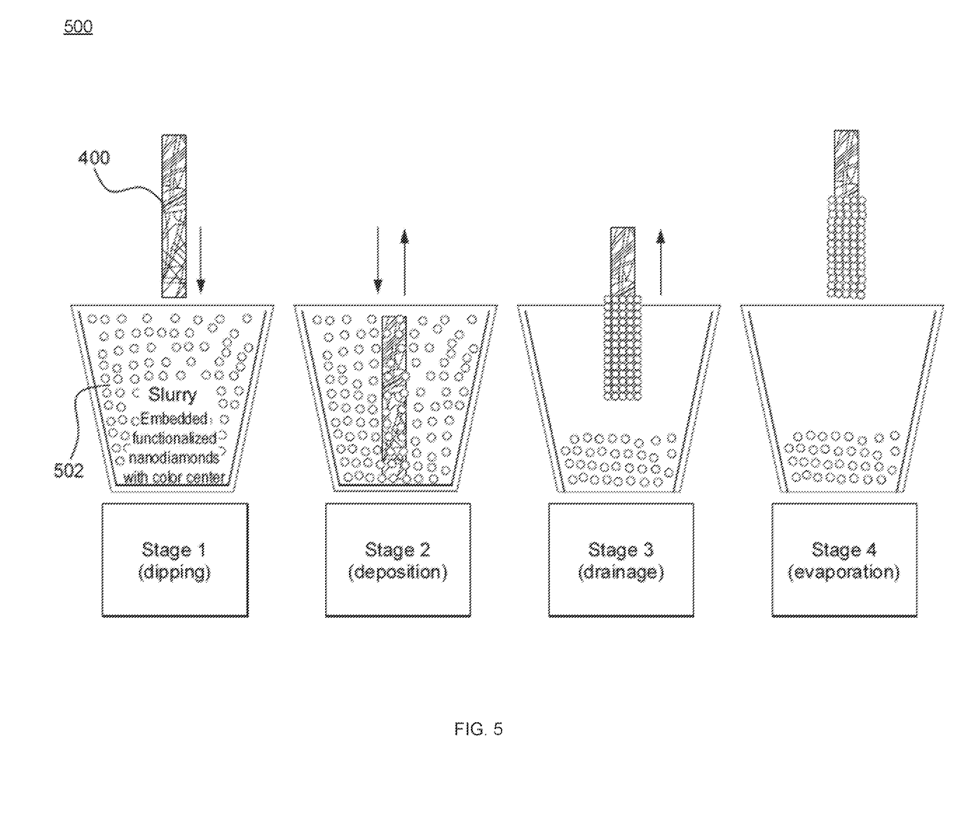

In some implementations, fabricating the quantum sensor embedded within the part may include dip coating 314 at least a portion of the part in a slurry of the quantum material hosting the quantum vacancy defects. For instance, and referring at least to the example implementation of FIG. 5, an example process 500 (e.g., of fabrication process 110) is shown. In the example, the stages include stage 1 - dipping part 400 into a slurry (e.g., slurry 502), stage 2 – deposition, stage 3 – drainage, and stage 4 – evaporation. For instance, fabricating a quantum sensor for part 400 may be achieved by dip coating the part (or at least a portion of the part) in a slurry containing quantum materials with vacancy defects, providing an efficient method for applying a uniform layer of quantum material directly to the part’s surface. In stage 1, part 400 is submerged in a slurry, which is a fluid suspension of quantum material—such as nanodiamonds with NV centers—dispersed in a liquid medium. This slurry is carefully formulated to ensure the quantum material is well-dispersed, preventing clumping and ensuring an even coating. The slurry may also include binders or additives to improve adhesion to the part’s surface, as well as stabilizing agents to keep the nanodiamond particles in suspension to avoid settling. It will be appreciated after reading the present disclosure that implementations may include a curing step utilizing heat, convection, ultraviolet light, and/or other combined mechanisms.

In stage 2, known as deposition, part 400 is withdrawn from the slurry at a controlled speed. This step allows a thin, uniform layer of quantum material to form on the part’s surface, with the withdrawal rate directly affecting the coating thickness. In some implementations, only a portion of the part, as needed based on the application, may need to be dip coated. Multiple dips can be performed in succession if a thicker layer is needed for certain applications. Stage 3, or drainage, follows as excess slurry flows off the part, leaving an even, thin layer of quantum material. Controlled drainage is beneficial to maintain a uniform coating without leaving uneven spots or pooling, which could affect the performance of the quantum sensor. Finally, in stage 4, evaporation, part 400 undergoes drying and curing to solidify the slurry layer and secure the quantum material onto the surface. This may involve air drying or gentle heating to evaporate the liquid medium, followed by additional curing with heat to stabilize the coating. The curing process ensures that the quantum particles are securely adhered, creating a stable coating with embedded vacancy defects that remain accessible for sensing.

The dip-coating process preserves the quantum properties of the vacancy defects, allowing NV centers or other quantum defects within the material to retain their fluorescence and sensitivity to magnetic, electric, or thermal fields. This is beneficial for the part’s functionality as a sensing device, as it ensures the quantum sensors can reliably interact with environmental changes. Additionally, the dip-coated quantum layer can be customized for specific applications by modifying the slurry composition. Functional groups or additional surface treatments can be added to enhance chemical stability, or environmental resistance, making the quantum sensor suitable for conditions such as high temperatures. In some implementations, part 400 may be dip coated after being embedded with functionalized nanodiamonds, or dip coated instead of having embedded functionalized nanodiamonds.

The terminology used herein is for the purpose of describing particular implementations only and is not intended to be limiting of the disclosure. As used herein, the singular forms "a", "an" and "the" are intended to include the plural forms as well, unless the context clearly indicates otherwise. As used herein, the language “at least one of A and B” (and the like) as well as “at least one of A or B” (and the like) should be interpreted as covering only A, only B, or both A and B, unless the context clearly indicates otherwise. It will be further understood that the terms "comprises" and/or "comprising," when used in this specification, specify the presence of stated features, integers, steps (not necessarily in a particular order), operations, elements, and/or components, but do not preclude the presence or addition of one or more other features, integers, steps (not necessarily in a particular order), operations, elements, components, and/or groups thereof.

The corresponding structures, materials, acts, and equivalents (e.g., of all means or step plus function elements) that may be in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications, variations, substitutions, and any combinations thereof will be apparent to those of ordinary skill in the art without departing from the scope and spirit of the disclosure. The implementation(s) were chosen and described in order to explain the principles of the disclosure and the practical application, and to enable others of ordinary skill in the art to understand the disclosure for various implementation(s) with various modifications and/or any combinations of implementation(s) as are suited to the particular use contemplated.

Having thus described the disclosure of the present application in detail and by reference to implementation(s) thereof, it will be apparent that modifications, variations, and any combinations of implementation(s) (including any modifications, variations, substitutions, and combinations thereof) are possible without departing from the scope of the disclosure defined in the appended claims.

What is claimed is:

1. A method comprising:
fabricating a quantum sensor embedded within a part, wherein the quantum sensor includes:
a quantum material hosting quantum vacancy defects;
wherein the quantum vacancy defects have quantum color centers; and
wherein the quantum vacancy defects, when exposed to a stimulus, emit a measurable signal from the quantum color centers.

2. The method of claim 1, wherein the quantum material includes functionalized nanodiamond particles, and wherein the quantum vacancy defects include one of nitrogen vacancy (NV) defects, SiC vacancy defects, and h-BN vacancy defects.

3. The method of claim 1, wherein the quantum material includes composite particles with a core-shell structure.

4. The method of claim 1, wherein fabricating the quantum sensor embedded within the part includes at least one of:
creating the quantum vacancy defects;
fabricating the quantum material hosting the quantum vacancy defects within a bulk substrate; and
grinding the bulk substrate into another form.

5. The method of claim 1, wherein fabricating the quantum sensor embedded within the part includes 3D printing the part using a plastic filament that is embedded with the quantum material hosting the quantum vacancy defects.

6. The method of claim 5, wherein 3D printing the part using the plastic filament that is embedded with the quantum material hosting the quantum vacancy defects includes at least one of:
printing at least a first portion of the plastic filament that is embedded with the quantum material hosting the quantum vacancy defects using a first nozzle; and
printing at least a second portion of the plastic filament without the quantum material hosting the quantum vacancy defects using a second nozzle.

7. The method of claim 1, wherein fabricating the quantum sensor embedded within the part includes dip coating at least a portion of the part in a slurry of the quantum material hosting the quantum vacancy defects.

8. A computer program product residing on a computer readable storage medium having a plurality of instructions stored thereon which, when executed across one or more processors, causes at least a portion of the one or more processors to perform operations comprising:
fabricating a quantum sensor embedded within a part, wherein the quantum sensor includes:
a quantum material hosting quantum vacancy defects;
wherein the quantum vacancy defects have quantum color centers; and
wherein the quantum vacancy defects, when exposed to a stimulus, emit a measurable signal from the quantum color centers.

9. The computer program product of claim 8, wherein the quantum material includes functionalized nanodiamond particles, and wherein the quantum vacancy defects include nitrogen vacancy (NV) defects, SiC vacancy defects, and h-BN vacancy defects.

10. The computer program product of claim 8, wherein the quantum material includes composite particles with a core-shell structure.

11. The computer program product of claim 8, wherein fabricating the quantum sensor embedded within the part includes at least one of:
creating the quantum vacancy defects;
fabricating the quantum material hosting the quantum vacancy defects within a bulk substrate; and
grinding the bulk substrate into another form.

12. The computer program product of claim 8, wherein fabricating the quantum sensor embedded within the part includes 3D printing the part using a plastic filament that is embedded with the quantum material hosting the quantum vacancy defects.

13. The computer program product of claim 12, wherein 3D printing the part using the plastic filament that is embedded with the quantum material hosting the quantum vacancy defects includes at least one of:
printing at least a first portion of the plastic filament that is embedded with the quantum material hosting the quantum vacancy defects using a first nozzle; and
printing at least a second portion of the plastic filament without the quantum material hosting the quantum vacancy defects using a second nozzle.

14. The computer program product of claim 8, wherein fabricating the quantum sensor embedded within the part includes dip coating at least a portion of the part in a slurry of the quantum material hosting the quantum vacancy defects.

15. A part comprising:
a quantum sensor embedded within the part, wherein the quantum sensor includes:
a quantum material hosting quantum vacancy defects;
wherein the quantum vacancy defects have quantum color centers; and
wherein the quantum vacancy defects, when exposed to a stimulus, emit a measurable signal from the quantum color centers.

16. The part of claim 15, wherein the quantum material includes functionalized nanodiamond particles, and wherein the quantum vacancy defects include nitrogen vacancy (NV) defects, SiC vacancy defects, and h-BN vacancy defects.

17. The part of claim 15, wherein the quantum material hosting the quantum vacancy defects is at least one of:
created;
fabricated within a bulk substrate; and
ground into another form.

18. The part of claim 15, wherein the part is fabricated by 3D printing the part using a plastic filament that is embedded with the quantum material hosting the quantum vacancy defects.

19. The part of claim 18, wherein the part includes at least one of:
at least a first portion of the plastic filament that is embedded with the quantum material hosting the quantum vacancy defects is printed using a first nozzle; and
at least a second portion of the plastic filament without the quantum material hosting the quantum vacancy defects is printed using a second nozzle.

20. The part of claim 15, wherein at least a portion of the part is dip coated in a slurry of the quantum material hosting the quantum vacancy defects.
